(19) United States
(12) Patent Application Publication
(10) Pub. No.: US 2026/0103800 A1
(43) Pub. Date: Apr. 16, 2026

(54) METHODS OF DEPOSITING METAL-CONTAINING FILMS HAVING A COMPOSITION GRADIENT

(71) Applicant: Applied Materials, Inc., Santa Clara, CA (US)

(72) Inventors: Lisa J. Enman, Sunnyvale, CA (US); Lakmal C. Kalutarage, San Jose, CA (US); Feng Q. Liu, San Jose, CA (US); Mark Saly, Santa Clara, CA (US); Jeffrey W. Anthis, Redwood City, CA (US); Parmish Kaur, Espoo (FI); Anjali Sood; Brice Jean Eychenne, Kirkkonummi (FI); Chandan Das, Singapore (SG)

(73) Assignee: Applied Materials, Inc., Santa Clara, CA (US)

(21) Appl. No.: 18/912,044

(22) Filed: Oct. 10, 2024

(51) Int. Cl. C23C 16/455; C23C 16/02; C23C 16/40

(52) U.S. Cl. CPC C23C 16/45529; C23C 16/0272; C23C 16/403

(57) ABSTRACT

Methods of depositing metal-containing films having a composition gradient (i.e., gradient films) are described. The gradient films may be deposited by an atomic layer deposition (ALD) process or a chemical vapor deposition (CVD) process. The gradient film includes at least one metal selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu). A metallic film is deposited on the gradient film, the metallic film including one or more of copper (Cu), ruthenium (Ru), cobalt (Co), tungsten (W), or molybdenum (Mo).

### TECHNICAL FIELD

Embodiments of the present disclosure pertain to the field of electronic device manufacturing. More particularly, embodiments of the present disclosure are directed methods of depositing metal-containing films having a composition gradient.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Semiconductor devices are typically fabricated by sequentially depositing insulating or dielectric layers, conductive layers, and semiconductor layers of material over a substrate, and patterning the various material layers using lithography to form circuit components and elements thereon. The conductive layers facilitate electrical wiring to various electrical components including transistors, amplifiers, inverters, control logic, memory, power management circuits, buffers, filters, resonators, capacitors, inductors, resistors, and the like.

The transistor is a key component of most integrated circuits. Many transistors may be formed on a semiconductor device in addition to capacitors, inductors, resistors, diodes, conductive lines, or other elements, depending on the circuit design. Control of the dimensions of the integrated circuit device structure is a key challenge for present and future technology generations.

In high aspect ratio features, such as vias comprising a top opening, a middle region separated by two sidewalls, and a bottom, it remains a challenge to meet seed layer step coverage requirements using conventional physical vapor deposition (PVD) processes. As a result of depositing seed layer stacks using conventional PVD, there are often defects in the deposited seed layer, such as partial fills, voids, and/or seams. Moreover, since seed layer stacks deposited by PVD cannot deposit sufficiently in the middle region and/or bottom of the via without closing the top opening, it also remains a challenge to electrochemically deposit a metallic film to fill the via.

Accordingly, there is a need for methods of depositing seed layer stacks to meet step coverage requirements.

### SUMMARY

One or more embodiments are directed to a processing method comprising: depositing a gradient film on a substrate; and depositing a metallic film on the gradient film. In one or more embodiments, the gradient film includes at least one metal selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu). In one or more embodiments, the gradient film has a thickness in a range of from 1 Å to 500 nm. In one or more embodiments, the metallic film includes one or more of copper (Cu), ruthenium (Ru), cobalt (Co), tungsten (W), or molybdenum (Mo).

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the Figures in which like references indicate similar elements.

FIG. 1 illustrates a process flow diagram of a method according to one or more embodiments of the present disclosure;

FIG. 2A illustrates a cross-sectional view of a substrate according to one or more embodiments of the present disclosure;

FIG. 2B illustrates a cross-sectional view of a substrate according to one or more embodiments of the present disclosure;

FIG. 2C illustrates a cross-sectional view of a substrate according to one or more embodiments of the present disclosure;

FIG. 3A illustrates a schematic representation of processing a substrate comprising a through-glass via (TGV) according to one or more embodiments of the present disclosure;

FIG. 3B illustrates a schematic representation of processing a substrate comprising a through-silicon via (TSV) according to one or more embodiments of the present disclosure; and

FIG. 4 illustrates a schematic representation of a processing system according to one or more embodiments of the disclosure.

### DETAILED DESCRIPTION

The term “about” as used herein means approximately or nearly and in the context of a numerical value or range set forth means a variation of ±15% or less of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a structure in use or operation in addition to the orientation depicted in the Figures. For example, if the structure in the Figures is turned over, elements described as “below” or “beneath” other elements or features would then be oriented “above” the other elements or features. Thus, the exemplary term “below” may encompass both an orientation of above and below. The structure may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “some embodiments,” “certain embodiments,” “one or more embodiments,” or “an embodiment” means that a particular feature, structure, material, or characteristic described in connection with the embodiment is included in at least one embodiment of the disclosure. Thus, the appearances of the phrases such as “in one embodiment,” “in some embodiments,” “in certain embodiments,” “in one or more embodiments,” or “in an embodiment” in various places throughout this specification are not necessarily referring to the same embodiment of the disclosure. Furthermore, the particular features, structures, materials, or characteristics may be combined in any suitable manner in one or more embodiments.

As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon (including doped silicon or undoped silicon), silicon oxide, strained silicon, silicon on insulator (SOI), carbon doped silicon oxides, amorphous silicon, germanium, gallium arsenide, and any other materials such as metals, metal nitrides, metal alloys, and other conductive materials, depending on the application. In one or more embodiments, the substrate includes an insulating or dielectric material and a conductive material, such as, for example, a semiconductor material. Substrates as described herein can include semiconductor materials without limitation. The substrate can, for example, include one or more of silicon (Si), silicon oxide (SiO₂), glass, quartz, silicon nitride (Si₃N₄), or silicon oxycarbonitride (SiOCN).

Substrates may be exposed to a pre-treatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, or combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls comprising, for example, a dielectric material, and a bottom extending into the substrate, the bottom comprising, for example, a metallic material, or vias which have one or more sidewall extending into the substrate to a bottom, a through-glass via (TGV), or a through-silicon via (TSV).

As used herein, a “through-glass via (TGV)” is a type of interconnect used in wafer-level packaging. A TGV is a vertical electrical connection, or via, that passes completely through the glass substrate to pass electrical signals between stacked die.

The composition of glass can be changed allowing tailoring of glass properties to specific applications. Glass in comparison to silicon has many properties that make it a suitable substrate for RF components such as, for example: ultra-high resistivity and low electrical loss.

As used herein, a “through-silicon via (TSV)” is a type of interconnect used in wafer-level packaging. A TSV is a vertical electrical connection, or via, that passes completely through the substrate to pass electrical signals between stacked die.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1. As used herein, a “high aspect ratio feature” has an aspect ratio in a range of from 10:1 to 150:1.

As used herein, “selective” deposition of materials can be accomplished in a variety of ways. For instance, some processes may have inherent selectivity to surfaces based on their surface chemistry. These processes are rare, and are typically specific to the reactants used, materials formed and the substrate surfaces. A chemical precursor may react selectively with one surface relative to another surface (e.g., metallic vs. dielectric, or vice versa). Process parameters such as pressure, substrate temperature, precursor partial pressures, and/or gas flows may be modulated to modulate the chemical kinetics of a particular surface reaction.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

As used in this specification and the appended claims, the terms “precursor,” “reactant,” “reactive gas,” “reactive species,” and the like are used interchangeably to refer to any gaseous species or vapor species that can react with the substrate surface.

As used herein, “chemical vapor deposition (CVD)” refers to a process in which a substrate surface is exposed to precursors and/or reactants simultaneously or substantially simultaneously. As used herein, “substantially simultaneously” refers to either co-flow or where there is overlap for a majority of exposures of the precursors and/or reactants. As used herein, “pulsed CVD” refers to a process in which one of the precursor or the reactant is pulsed intermittently, and the other of the precursor of the reactant is flowed continuously. Plasma-enhanced chemical vapor deposition (PECVD) methods add a plasma exposure to traditional CVD methods. In some PECVD methods, an inert gas is provided as the plasma. Embodiments described herein in reference to a PECVD process can be carried out using any suitable deposition system.

“Atomic layer deposition” or “cyclical deposition” as used herein refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially.

As used herein, the terms “purge” or “purging” each independently include any suitable purge process that removes unreacted precursor/reactant, reaction products, and by-products from the process region (e.g., a processing chamber). The suitable purge process includes moving the substrate through a gas curtain to a portion or sector of the processing region that contains none or substantially none of the precursor/reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), or argon (Ar). In some embodiments, the first reactive species is purged from the processing chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Plasma-enhanced atomic layer deposition (PEALD) methods add a plasma exposure to traditional ALD methods. In some PEALD methods, an inert gas is provided as the plasma. Embodiments described herein in reference to a PEALD process can be carried out using any suitable deposition system.

As used herein, the terms “thermal” or “thermal process(es)” each independently refer to a deposition technique that does not involve the use of plasma. As used herein, the term “plasma” refers to a composition have ionically charged species and uncharged neutral and radical species.

As used herein, as will be understood by the skilled artisan, a layer/film which is “conformal” or “conformally deposited” refers to a layer/film where the thickness is about the same throughout. A layer/film which is conformal varies in thickness by less than or equal to about 5 %, 2 %, 1 % or 0.5 %.

Embodiments of the present disclosure are directed to methods of depositing metal-containing films having a composition gradient (i.e., gradient films). Advantageously, the gradient films described herein adhere to silicon-containing substrates, such as, for example, one or more of silicon (Si), silicon oxide (SiO₂), glass, quartz, silicon nitride (Si₃N₄), silicon oxycarbonitride (SiOCN), a through-glass via (TGV), or a through-silicon via (TSV). For example, aluminum oxide (AlOx) forms chemical bonds with a silicon oxide (SiO₂) substrate, causing adhesion.

Advantageously, the gradient films described herein adhere to a seed layer deposited thereon, such as, for example, one or more of copper (Cu), ruthenium (Ru), cobalt (Co), tungsten (W), or molybdenum (Mo).

Advantageously, the gradient films described herein adhere to a silicon-containing substrate on one side, and a seed layer on the other side.

Some embodiments advantageously provide methods of depositing a gradient film directly on a silicon-containing substrate, and depositing a metallic film (including one or more of copper (Cu), ruthenium (Ru), cobalt (Co), tungsten (W), or molybdenum (Mo)) directly on the gradient film.

Since seed layer stacks deposited by PVD cannot deposit sufficiently in the middle and/or bottom of the via without closing the top opening, it also remains a challenge to electrochemically deposit a metallic film due to defects in the deposited seed layer, such as partial fills, voids, and/or seams.

Advantageously, in accordance with one or more embodiments where the gradient film is deposited by a chemical vapor deposition (CVD) process or an atomic layer deposition (ALD) process, the gradient film is deposited in a manner that meets step coverage requirements. The gradient films deposited by a chemical vapor deposition (CVD) process or an atomic layer deposition (ALD) process have improved conformality compared to seed layer stacks deposited by PVD, thereby meeting step coverage requirements. Advantageously, a metallic film can be electrochemically deposited on the gradient film to a fill a via, for example, where the metallic film is free of seams and/or voids.

The gradient films described herein can advantageously be deposited in high aspect ratio features a manner that meets step coverage requirements. Advantageously, depositing the gradient films in high aspect ratio features will allow for greater packing density of the features and, as such, provide improved device (e.g., interconnect) connection.

The gradient films and the metallic films deposited on the gradient films can be used for, without limitation, wafer-level packaging applications.

The embodiments of the disclosure are described by way of the Figures, which illustrate substrates, methods of processing the substrates, and processing systems for performing the methods and processing the substrates, in accordance with one or more embodiments of the disclosure. The substrates and processing systems shown are merely illustrative possible uses for the disclosed processes, and the skilled artisan will recognize that the disclosed substrates and processing systems are not limited to the illustrated applications.

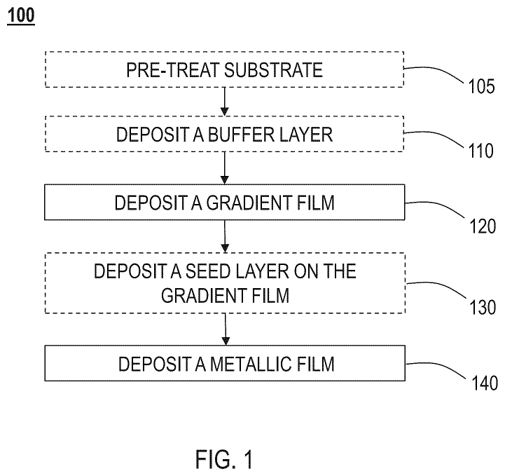

FIG. 1 illustrates a process flow diagram of a method 100 according to one or more embodiments of the present disclosure. The operations of the method 100 can be performed in any suitable order. In one or more embodiments, the operations of the method 100 are performed sequentially in the order illustrated in FIG. 1. One or more of the operations of the method 100 may be repeated. One or more of the operations of the method 100 may not be performed, e.g., where the operation is denoted as optional using dashed lines in FIG. 1. It will be appreciated by the skilled artisan that the substrate on which the processes are performed on can be provided (e.g., made available for processing) with one or more operations already completed.

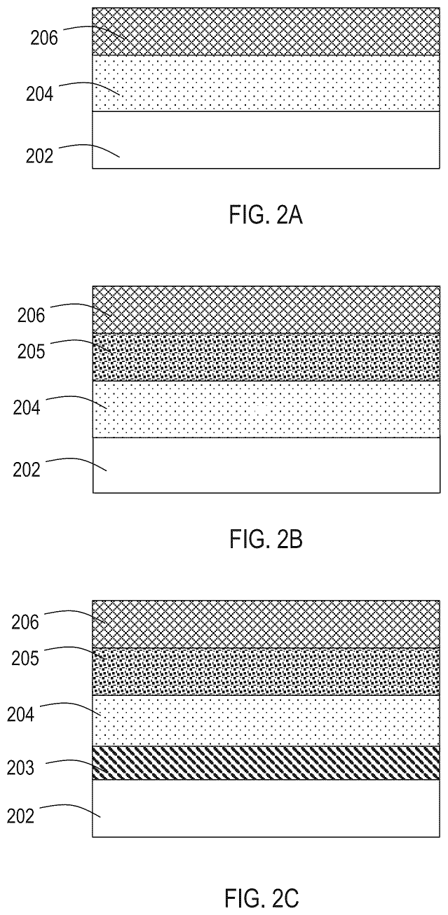

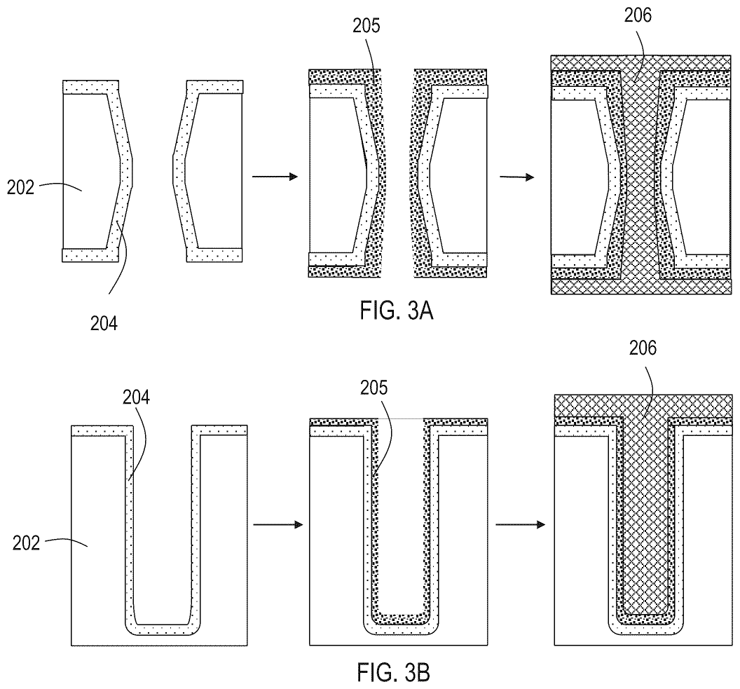

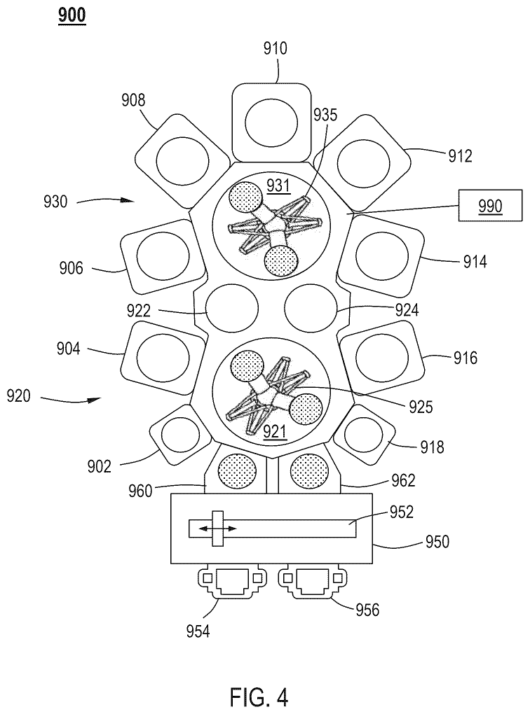

FIG. 2A-2C illustrate cross-sectional views of a substrate in accordance with the method 100. FIG. 3A illustrates a schematic representation of processing a substrate comprising a through-glass via (TGV). FIG. 3B illustrates a schematic representation of processing a substrate comprising a through-silicon via (TSV). FIG. 4 illustrates a schematic representation of a processing system 900 for processing the substrates shown and/or performing the methods described herein.

In FIG. 1, the method 100 begins at operation 105 by optionally pre-treating the substrate 202. The pre-treatment at operation 105 can be any suitable pre-treatment process known to the skilled artisan. Suitable pre-treatments include, but are not limited to, exposing the substrate to one or more of thermal nitrogen (N₂), thermal helium (He), thermal argon (Ar), thermal oxygen (O₂), thermal ozone (O₃), a plasma of one or more of nitrogen (N₂), helium (He), argon (Ar), oxygen (O₂), ozone (O₃), or an etch process.

Referring to FIG. 2A-2C, at operation 110, the method 100 optionally includes depositing a buffer layer 203 directly on the substrate 202.

The substrate 202 can be any suitable substrate material. The substrate 202 comprises one or more of silicon (Si), silicon oxide (SiO₂), glass, quartz, silicon nitride (Si₃N₄), silicon oxycarbonitride (SiOCN), a through-glass via (TGV), or a through-silicon via (TSV). In FIG. 3A, the substrate 202 comprises a through-glass via (TGV). In FIG. 3B, the substrate 202 comprises a through-silicon via (TSV).

Although a few examples of materials from which the substrate 202 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

The buffer layer 203 comprises one or more of silicon oxide (SiO₂), silicon nitride (Si₃N₄), or silicon oxycarbonitride (SiOCN). The buffer layer 203 has a thickness in a range of from 5 nm to 5 μm. Without intending to be bound by any particular theory and without limitation, the buffer layer 203 can be used to prevent cracking and damage to the substrate 202.

Referring to FIG. 2A-2B, a gradient film 204 is deposited directly on the substrate 202 in accordance with operation 120 of the method 100. In FIG. 2C, the buffer layer 203 is deposited directly on the substrate 202, and the gradient film 204 is deposited directly on the buffer layer 203.

The gradient film 204 includes at least one metal selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu).

Any suitable metallic precursor comprising at least one metal selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu) can be used to deposit the gradient film 204.

In one or more embodiments, the metallic precursor comprising aluminum (Al), i.e., an aluminum-containing precursor, includes one or more of trimethylaluminum (TMA), triethylaminum (TEA), dimethylaluminum chloride ([(CH₃)₂AlCl]₂), aluminum trichloride (AlCl₃), trineopentylaluminum (e.g., an aluminum complex of 2,2 dimethyl propane).

In one or more embodiments, the metallic precursor comprising ruthenium (Ru), i.e., a ruthenium-containing precursor, includes one or more of bis(ethylcyclopentadienyl)ruthenium(II) (Ru(EtCp)₂), bis(cyclopentadienyl)ruthenium(II) (Ru(Cp)₂), 1-methyl-3-isopropyl-benzene 1,3-cyclohexadiene ruthenium, 1-ethyl-benzene 1,3-cyclohexadiene ruthenium, 1-ethyl-benzene 1-ethyl-1,3-cyclohexadiene ruthenium, or (1-ethyl-1,4-cyclohexadiene)(ethylbenzene)ruthenium(0).

In one or more embodiments, the metallic precursor comprising cobalt (Co), i.e., a cobalt-containing precursor, includes one or more of (3,3-Dimethyl-1-butyne)dicobalt hexacarbonyl, Cyclopentadienylcobalt dicarbonyl, dicobalt octacarbonyl, Bis(1,4-di-tert-butyl-1,3-diazadienyl)cobalt, or bis(N-tert-butyl-N'-ethylpropionamidinato) cobalt.

In one or more embodiments, the metallic precursor comprising zinc (Zn), i.e., a zinc-containing precursor, includes diethylzinc.

In one or more embodiments, the metallic precursor comprising molybdenum (Mo), i.e., a molybdenum-containing precursor, includes one or more of molybdenum pentachloride (MoCl₅) molybdenum oxytetrachloride (MoOCl₄), molybdenum dichloride dioxide (MoO₂Cl₂), molybdenum hexafluoride (MoF₆), or Bis(tert-butylimido)-bis(diethylamido)molybdenum.

In one or more embodiments, the metallic precursor comprising titanium (Ti), i.e., a titanium-containing precursor, includes one or more of titanium tetrachloride (TiCl₄), tetrakis(dimethylamido)titanium (TDMAT), or titanium(IV) isopropoxide (Ti(OiPr)₄).

In one or more embodiments, the metallic precursor comprising tungsten (W), i.e., a tungsten-containing precursor, includes one or more of tungsten hexafluoride (WF₆), tungsten hexachloride (WCl₆), tungsten (VI) oxytetrachloride (WOCl₄), tungsten pentachloride (WCl₅), tungsten hexacarbonyl, or bis(tert-butylimino)bis(dimethylamino)tungsten.

In one or more embodiments, the metallic precursor comprising iridium, i.e., an iridium-containing precursor, includes one or more of iridium(III) acetylacetonate (Ir(acac)₃), Ir(CpMe)(COD), Ir(CpEt)(COD), or Ir(CO)₃(tBu₃Cyp).

In one or more embodiments, the metallic precursor comprising copper (Cu), i.e., a copper-containing precursor, includes one or more of bis(dimethylamino-2-propoxy)copper or bis(ethylmethylamino-2-propoxy)copper.

Any suitable reactant can be used to deposit the gradient film 204. The reactant can include a thermal reactant or a plasma of the reactant. In one or more embodiments, the reactant is an oxygen-containing reactant. In some embodiments, the reactant comprises one or more of oxygen (O₂), ozone (O₃), water (H₂O), nitrous oxide (N₂O), or an alcohol.

In some embodiments where the reactant comprises a plasma of oxygen (O₂), the plasma further comprises an inert gas.

In one or more embodiments, the alcohol has a general formula of R¹—O—R², where R¹ and R² are independently selected from H, an alkyl group, or an aryl group having in a range of from 1 to 12 carbon atoms. In one or more embodiments, the alcohol comprises, consists essentially of, or consists of ethanol. In one or more embodiments, the alcohol comprises, consists essentially of, or consists of tert-butanol.

In some embodiments, the reactant comprises hydrogen (H₂). In some embodiments, the reactant comprises diethylzinc.

Each of the metallic precursor and the reactant are independently selected based upon the desired composition of the gradient film 204.

In some embodiments, the gradient film 204 is deposited by a chemical vapor deposition (CVD) process. In some embodiments, the gradient film 204 is deposited by thermal CVD. In some embodiments, the gradient film 204 is deposited by a plasma-enhanced CVD (PECVD).

In some embodiments, the gradient film 204 is deposited by an atomic layer deposition (ALD) process. In some embodiments, the gradient film 204 is deposited by thermal ALD. In some embodiments, the gradient film 204 is deposited by plasma-enhanced ALD (PEALD).

In specific embodiments, the gradient film 204 is deposited by a process cycle comprising the following sequence: (M₁/R)ₐ+{[(M₁/R)_{b}+(M₂/R)_{c}]_{d}}ₓ+(M₂/R)ₑ, where M₁ is a first metallic precursor, M₂ is a second metallic precursor that is the same as the first metallic precursor or different from the first metallic precursor, R is a reactant, “a” is an integer in a range of from 0 to 1000, “b” is an integer in a range of from 1 to 100, “c” is an integer in a range of from 1 to 100, “d” is an integer in a range 1 to 1000, “e” is an integer in a range of from 0 to 1000, and “x”is an integer in a range of from 1 to 5.

The first metallic precursor, the second metallic precursor, and the third metallic precursor are independently selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu).

The process cycle can be referred to in three (3) sequences: (M₁/R)ₐ defining a first sequence, {[(M₁/R)_{b}+(M₂/R)_{c}]_{d}}ₓ defining a second sequence, and (M₂/R)ₑ defining a third sequence.

The integers for each of “a,” “b,” “c,” “d,” “e,” and “x” are representative of the number of times that the stated sequence (i.e., the first sequence, the second sequence, and/or the third sequence), or part of the sequence (as the case may be) is repeated. The stated sequence can be repeated any suitable number of times based on the stated integer ranges, and the integers for each of “a,” “b,” “c,” “d,” “e,” and “x” depend on the desired thickness of the gradient film 204.

For example, in (M₁/R)ₐ where “a” is 1 means that the respective pulse of M₁ and pulse of R occurs 1 time. For example, in (M₁/R)ₐ where “a” is 2 means that the respective pulse of M₁ and pulse R occurs 2 times.

In specific embodiments, with (M₁/R)ₐ defining the first sequence, {[(M₁/R)_{b}+(M₂/R)_{c}]_{d}}ₓ defining the second sequence, and (M₂/R)ₑ defining the third sequence, M₁ is an aluminum-containing precursor, M₂ is a ruthenium-containing precursor, and R is an oxygen-containing reactant.

In specific embodiments, the first sequence comprises exposing the substrate 202 to one pulse of the aluminum-containing precursor with an inert gas purge, and one pulse of the oxygen-containing reactant with an inert gas purge. In specific embodiments, the first sequence is performed 100 times, i.e., “a” is 100. Accordingly, in specific embodiments, the first sequence (M₁/R)ₐ is defined as (aluminum-containing precursor/oxygen-containing reactant)₁₀₀.

In specific embodiments, the second sequence comprises, in part (M₁/R)_{b}+(M₂/R)_{c}, exposing the substrate 202 to one pulse of the aluminum-containing precursor with an inert gas purge, one pulse of the oxygen-containing reactant with an inert gas purge, one pulse of the ruthenium-containing precursor with an inert gas purge, and one pulse of the oxygen-containing reactant with the inert gas purge.

In specific embodiments, “b” is 10, “c” is 1, “d” is 5, and “x” is 1, and the second sequence {[(M₁/R)_{b}+(M₂/R)_{c}]_{d}}ₓ is defined as {[(aluminum-containing precursor/oxygen-containing reactant)₁₀+(ruthenium-containing precursor/oxygen-containing reactant)₁]₅}₁.

In specific embodiments, “b” is 5, “c” is 1, “d” is 5, and “x” is 2, and the second sequence {[(M₁/R)_{b}+(M₂/R)_{c}]_{d}}ₓ is defined as {[(aluminum-containing precursor/oxygen-containing reactant)₅+(ruthenium-containing precursor/oxygen-containing reactant)₁]₅}₂.

In specific embodiments, “b” is 1, “c” is 1, “d” is 25, and “x” is 3, and the second sequence {[(M₁/R)_{b}+(M₂/R)_{c}]_{d}}ₓ is defined as {[(aluminum-containing precursor/oxygen-containing reactant)₁+(ruthenium-containing precursor/oxygen-containing reactant)₁]₂₅}₃.

In specific embodiments, “b” is 1, “c” is 5, “d” is 10, and “x” is 4, and the second sequence {[(M₁/R)_{b}+(M₂/R)_{c}]_{d}}ₓ is defined as {[(aluminum-containing precursor/oxygen-containing reactant)₁+(ruthenium-containing precursor/oxygen-containing reactant)₅]₁₀}₄.

In specific embodiments, the third sequence comprises exposing the substrate 202 to one pulse of the ruthenium-containing precursor with an inert gas purge, and one pulse of the oxygen-containing reactant with an inert gas purge. In specific embodiments, the third sequence is performed 100 times, i.e., “e” is 100. Accordingly, in specific embodiments, the third sequence (M₂/R)ₑ is defined as (ruthenium-containing precursor/oxygen-containing reactant)₁₀₀.

In one or more embodiments, the gradient film 204 has a gradient in oxygen composition, a gradient in oxygen composition and metal composition, a gradient in oxygen composition and nitrogen composition, and/or a gradient in oxygen composition and sulfur composition. The gradient film 204 having a gradient in oxygen composition, a gradient in oxygen composition and metal composition, a gradient in oxygen composition and nitrogen composition, and/or a gradient in oxygen composition and sulfur composition can be deposited using the process cycle (M₁/R)ₐ+{[(M₁/R)_{b}+(M₂/R)_{c}]_{d}}ₓ+(M₂/R)ₑ, as described herein.

In one or more embodiments, the gradient film 204 has a gradient in oxygen composition. In specific embodiments, the gradient film 204 includes one metal selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu) and an oxide of the one metal. In specific embodiments, the gradient film 204 comprises ruthenium (Ru) and ruthenium oxide (RuOx). In specific embodiments, the gradient film 204 consists essentially of ruthenium (Ru) and ruthenium oxide (RuOx). In specific embodiments, the gradient film 204 consists of ruthenium (Ru) and ruthenium oxide (RuOx).

The skilled artisan will recognize that the use of molecular formulae herein, e.g., ruthenium oxide (RuOx), and the like does not imply a specific stoichiometric relationship between the elements but merely the identity of the major components of the film. For example, RuOx refers to a film whose major composition comprises ruthenium (Ru) atoms and oxygen (O) atoms. In some embodiments, the major composition of the specified film (i.e., the sum of the atomic percent of the specified atoms) is greater than or equal to about 95%, 98%, 99% or 99.5% of the film, on an atomic basis. The skilled artisan will appreciate that there multiple instances where molecular formulae are used herein, and unless specifically indicated otherwise by the context, the molecular formulae do not imply a specific stoichiometric relationship between the elements, but merely the identity of the major components of the film.

In specific embodiments, the gradient film 204 comprises cobalt (Co) and cobalt oxide (CoOx). In specific embodiments, the gradient film 204 consists essentially of cobalt (Co) and cobalt oxide (CoOx). In specific embodiments, the gradient film 204 consists of cobalt (Co) and cobalt oxide (CoOx).

In some embodiments, the gradient film 204 has a gradient in oxygen composition and metal composition. In some embodiments, the gradient film 204 includes at least one metal selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu) and an oxide of the at least one metal.

In specific embodiments, the gradient film 204 comprises aluminum oxide (AlOx), aluminum ruthenium oxide (AlRuOx), and ruthenium (Ru). In specific embodiments, the gradient film 204 consists essentially of aluminum oxide (AlOx), aluminum ruthenium oxide (AlRuOx), and ruthenium (Ru). In specific embodiments, the gradient film 204 consists of aluminum oxide (AlOx), aluminum ruthenium oxide (AlRuOx), and ruthenium (Ru).

In specific embodiments, the process cycle described herein comprising the following sequence: (M₁/R)ₐ+{[(M₁/R)_{b}+(M₂/R)_{c}]_{d}}ₓ+(M₂/R)ₑ, is used to deposit the gradient film 204 comprising, consisting essentially of, or consisting of aluminum oxide (AlOx), aluminum ruthenium oxide (AlRuOx), and ruthenium (Ru).

In specific embodiments, the process cycle is defined as (TMA/water)₁₀₀+[(TMA/water)₁₀+((1-ethyl-1,4-cyclohexadiene)(ethylbenzene)ruthenium(0)/O₂)₁]₅+[(TMA/water)₅+((1-ethyl-1,4- cyclohexadiene)(ethylbenzene)ruthenium(0)/O₂)₁]₅+[(TMA/water)₁+((1-ethyl-1,4-cyclohexadiene)(ethylbenzene)ruthenium(0)/O₂)₁]₂₅+[(TMA/water)₁+((1-ethyl-1,4-cyclohexadiene)(ethylbenzene)ruthenium(0)/O₂)₅]₁₀+((1-ethyl-1,4- cyclohexadiene)(ethylbenzene)ruthenium(0)/O₂)₁₀₀.

In specific embodiments where the process cycle is defined as (TMA/water)₁₀₀+[(TMA/water)₁₀+((1-ethyl-1,4-cyclohexadiene)(ethylbenzene)ruthenium(0)/O₂)₁]₅+[(TMA/water)₅+((1-ethyl-1,4- cyclohexadiene)(ethylbenzene)ruthenium(0)/O₂)₁]₅+[(TMA/water)₁+((1-ethyl-1,4-cyclohexadiene)(ethylbenzene)ruthenium(0)/O₂)₁]₂₅+[(TMA/water)₁+((1-ethyl-1,4-cyclohexadiene)(ethylbenzene)ruthenium(0)/O₂)₅]₁₀+((1-ethyl-1,4- cyclohexadiene)(ethylbenzene)ruthenium(0)/O₂)₁₀₀, the gradient film 204 comprising, consisting essentially of, or consisting of aluminum oxide (AlOx), aluminum ruthenium oxide (AlRuOx), and ruthenium (Ru) comprises four monolayers to form the gradient film 204. In specific embodiments, the four monolayers includes a first monolayer directly on the substrate 202, a second monolayer directly on the first monolayer, a third monolayer directly on the second monolayer, a fourth monolayer directly on the third monolayer. In one or more embodiments, a metallic film such as metallic film 206 can be deposited directly on or on the fourth monolayer.

In specific embodiments where the process cycle is defined as (TMA/water)₁₀₀+[(TMA/water)₁₀+((1-ethyl-1,4-cyclohexadiene)(ethylbenzene)ruthenium(0)/O₂)₁]₅+[(TMA/water)₅+((1-ethyl-1,4- cyclohexadiene)(ethylbenzene)ruthenium(0)/O₂)₁]₅+[(TMA/water)₁+((1-ethyl-1,4-cyclohexadiene)(ethylbenzene)ruthenium(0)/O₂)₁]₂₅+[(TMA/water)₁+((1-ethyl-1,4-cyclohexadiene)(ethylbenzene)ruthenium(0)/O₂)₅]₁₀+((1-ethyl-1,4- cyclohexadiene)(ethylbenzene)ruthenium(0)/O₂)₁₀₀, the first monolayer comprises aluminum oxide (AlOx), the second monolayer comprises “aluminum oxide-rich” aluminum ruthenium oxide (AlRuOx), the third monolayer comprises “ruthenium-rich” aluminum ruthenium oxide (AlRuOx), and the fourth monolayer comprises ruthenium (Ru). As used herein, “aluminum oxide-rich” aluminum ruthenium oxide (AlRuOx) refers to a composition that has a greater concentration of aluminum atoms and oxygen atoms, collectively, than ruthenium atoms. As used herein, “ruthenium-rich” aluminum ruthenium oxide (AlRuOx) refers to a composition that has a greater concentration of ruthenium atoms than aluminum atoms and/or oxygen atoms.

In specific embodiments, the gradient film 204 comprises aluminum oxide (AlOx), aluminum copper oxide (AlCuOx), and copper aluminum (CuAl). In specific embodiments, the gradient film 204 consists essentially of aluminum oxide (AlOx), aluminum copper oxide (AlCuOx), and copper aluminum (CuAl). In specific embodiments, the gradient film 204 consists of aluminum oxide (AlOx), aluminum copper oxide (AlCuOx), and copper aluminum (CuAl).

In some embodiments, the gradient film 204 has a gradient in oxygen composition and nitrogen composition. In specific embodiments, the gradient film 204 includes one metal selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu), an oxide of the one metal, and a nitride of the one metal.

In specific embodiments, the gradient film 204 comprises molybdenum oxide (MoOx), molybdenum oxynitride (MoOxN), and molybdenum nitride (MoN). In specific embodiments, the gradient film 204 consists essentially of molybdenum oxide (MoOx), molybdenum oxynitride (MoOxN), and molybdenum nitride (MoN). In specific embodiments, the gradient film 204 consists of molybdenum oxide (MoOx), molybdenum oxynitride (MoOxN), and molybdenum nitride (MoN).

In some embodiments, the gradient film 204 has a gradient in oxygen composition and sulfur composition. In specific embodiments, the gradient film 204 including one metal selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu), an oxide of the one metal, and a sulfide of the one metal.

In specific embodiments, the gradient film 204 comprises molybdenum oxide (MoOx), molybdenum oxysulfide (MoOxS), and molybdenum disulfide (MoS₂). In specific embodiments, the gradient film 204 consists essentially of molybdenum oxide (MoOx), molybdenum oxysulfide (MoOxS), and molybdenum disulfide (MoS₂). In specific embodiments, the gradient film 204 consists of molybdenum oxide (MoOx), molybdenum oxysulfide (MoOxS), and molybdenum disulfide (MoS₂).

The gradient film 204 has a thickness in a range of from 1 Å to 500 nm. In one or more embodiments, the thickness of the gradient film 204 is in a range of from 5 nm to 500 nm. In specific embodiments, the thickness of the gradient film 204 is 25 nm.

Referring to FIGS. 1, 2A, and 2C, the method 100 optionally includes, at operation 130, depositing a seed layer 205 directly on the gradient film 204.

The seed layer 205 can be deposited directly on the gradient film 204 using any suitable deposition technique. In one or more embodiments, depositing the seed layer 205 directly on the gradient film 204 comprises a physical vapor deposition (PVD) process, a chemical vapor deposition (CVD) process, or an atomic layer deposition (ALD) process.

In one or more embodiments, the seed layer 205 comprises a conductive material, e.g., a metallic material, having a resistivity of less than or equal to 50 microhm-centimeter (μΩ·cm). In one or more embodiments, the seed layer 205 comprises one or more of copper (Cu), ruthenium (Ru), cobalt (Co), tungsten (W), or molybdenum (Mo). In one or more embodiments, the seed layer 205 has a thickness in a range of from 1 Å to 500 nm.

Referring to FIGS. 1, 2A, 2B, and 2C, the method 100 includes, at operation 140, depositing a metallic film 206 on the gradient film 204. In one or more embodiments, the metallic film 206 is deposited on the gradient film 204 by a physical vapor deposition (PVD) process, a chemical vapor deposition (CVD) process, or an atomic layer deposition (ALD) process.

In one or more embodiments, in FIG. 2A, the metallic film 206 is electrochemically deposited directly on the gradient film 204. In FIGS. 2B and 2C, the metallic film 206 is electrochemically deposited directly on the seed layer 205. As used herein, the terms “electrochemical deposition,” “electrochemically deposit[ed]/[ing],” each include a deposition process in which metals are removed from a chemical solution and deposited on a charged surface. The deposition process of “electrochemical deposition,” “electrochemically deposit[ed]/[ing],” as used herein, can be any suitable process known to the skilled artisan.

The metallic film 206 comprises one or more of copper (Cu), ruthenium (Ru), cobalt (Co), tungsten (W), or molybdenum (Mo). The metallic film 206 has a thickness in a range of from 50 nm to 50 μm.

FIG. 3A illustrates a schematic representation of processing the substrate 202 comprising a through-glass via (TGV). FIG. 3B illustrates a schematic representation of processing the substrate 202 comprising a through-silicon via (TSV). While FIGS. 3A and 3B each respectively illustrate a single feature, i.e., one through-glass via (TGV) and one through-silicon via (TSV), it will be understood and appreciated by the skilled artisan that the substrate 202 can include any suitable number of features, e.g., any suitable number of through-glass vias (TGVs) and/or through-silicon vias (TSVs).

In one or more embodiments, each of the through-glass via (TGV) or the through-silicon via (TSV) independently has an aspect ratio in a range of from 5:1 to 150:1. In one or more embodiments, each of the through-glass via (TGV) or the through-silicon via (TSV) independently comprises a “high aspect ratio feature” having an aspect ratio in a range of from 10:1 to 150:1.

In FIG. 3A, the gradient film 204 is shown as deposited directly on the through-glass via (TGV) in a first step, in accordance with operation 120 of the method 100. Then, in a second step, the seed layer 205 is deposited directly on the gradient film 204 in accordance with operation 130 of the method 100. Next, in a third step, the metallic film 206 is electrochemically deposited directly on the seed layer 205, in accordance with operation 140 of the method 100, to fill the through-glass via (TGV) without seams or voids. In one or more unillustrated embodiments, in accordance with the method 100, the metallic film 206 is electrochemically deposited directly on the gradient film 204 to fill the through-glass via (TGV) without seams or voids.

In FIG. 3B, the gradient film 204 is shown as deposited directly on through-silicon via (TSV) in a first step, in accordance with operation 120 of the method 100. Then, in a second step, the seed layer 205 is deposited directly on the gradient film 204 in accordance with operation 130 of the method 100. Next, in a third step, the metallic film 206 is electrochemically deposited directly on the seed layer 205, in accordance with operation 140 of the method 100, to fill the through-silicon via (TSV) without seams or voids. In one or more unillustrated embodiments, in accordance with the method 100, the metallic film 206 is electrochemically deposited directly on the gradient film 204 to fill the through-silicon via (TSV) without seams or voids.

Additional embodiments of the disclosure are directed to the processing system 900 (shown in FIG. 4) for processing the substrates shown and/or performing the methods described herein.

The processing system 900 includes at least one central transfer station 921, 931 with a plurality of sides. A robot 925, 935 is positioned within the central transfer station a, 931 and is configured to move a robot blade and a wafer, such as, for example, the substrate 202, to each of the plurality of sides.

The processing system 900 comprises a plurality of processing chambers 902, 904, 906, 908, 910, 912, 914, 916, and 918, also referred to as process stations, connected to the at least one central transfer station 921, 931. The various processing chambers provide separate processing regions isolated from adjacent process stations. The processing chambers can independently be any suitable processing chamber. The particular arrangement of processing chambers and components can be varied depending on the processing system and should not be taken as limiting the scope of the disclosure.

In the embodiment shown in FIG. 4, a factory interface 950 is connected to a front of the processing system 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the processing system 900. In the embodiment shown, the loading chamber 954 and unloading chamber 956 are sized to hold a wafer cassette with a plurality of wafers, e.g., a plurality of substrates, positioned within the cassette.

A robot 952 is within the factory interface 950 and can move between the loading chamber 954 and the unloading chamber 956. The robot 952 is capable of transferring a wafer (e.g., a substrate) from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock chamber 962 and the unloading chamber 956.

The processing system 900 shown has a first section 920 and a second section 930. The first section 920 is connected to the factory interface 950 through load lock chamber 960 and load lock chamber 962. The first section 920 includes at least one central transfer station 921 with at least one robot 925 positioned therein. The robot 925 can also be referred to as a robotic wafer transport mechanism. The at least one central transfer station 921 in the first section 920 is centrally located with respect to the load lock chamber 960 and the load lock chamber 962, process chambers 902, 904, 916, 918, and buffer chambers 922, 924. The robot 925 of some embodiments is a multi-arm robot capable of independently moving more than one wafer at a time. In one or more embodiments, the at least one central transfer station 921 in the first section 920 comprises more than one robotic wafer transfer mechanism. The robot 925 in the at least one central transfer station 921 is configured to move wafers between the chambers around the at least one central transfer station 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930, or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits and storage.

Processes may generally be stored in the memory of the system controller 990 as a software routine that, when executed by the processor, causes the processing system 900 to act in accordance with one or more embodiments of the present disclosure. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the operation such that the processes are performed.

One or more embodiments of the disclosure are directed to a non-transitory computer readable medium including instructions, that, when executed by a controller of a processing system, cause the processing system to perform the operations of the methods described herein and/or process the substrates shown.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A processing method comprising:
depositing a gradient film on a substrate, the gradient film including at least one metal selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu), the gradient film having a thickness in a range of from 1 Å to 500 nm; and
depositing a metallic film on the gradient film, the metallic film including one or more of copper (Cu), ruthenium (Ru), cobalt (Co), tungsten (W), or molybdenum (Mo).

2. The processing method of claim 1, wherein the gradient film has a gradient in oxygen composition, the gradient film including one metal selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu) and an oxide of the one metal.

3. The processing method of claim 2, wherein the gradient film includes ruthenium (Ru) and ruthenium oxide (RuOx), or cobalt (Co) and cobalt oxide (CoOx).

4. The processing method of claim 1, wherein the gradient film has a gradient in oxygen composition and metal composition, the gradient film including at least one metal selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu) and an oxide of the at least one metal.

5. The processing method of claim 4, wherein the gradient film includes aluminum oxide (AlOx), aluminum ruthenium oxide (AlRuOx), and ruthenium (Ru), or aluminum oxide (AlOx), aluminum copper oxide (AlCuOx), and copper aluminum (CuAl).

6. The processing method of claim 1, wherein the gradient film has a gradient in oxygen composition and nitrogen composition, the gradient film including one metal selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu), an oxide of the one metal, and a nitride of the one metal.

7. The processing method of claim 6, wherein the gradient film includes molybdenum oxide (MoOx), molybdenum oxynitride (MoOxN), and molybdenum nitride (MoN).

8. The processing method of claim 1, wherein the gradient film has a gradient in oxygen composition and sulfur composition, the gradient film including one metal selected from the group consisting of aluminum (Al), ruthenium (Ru), cobalt (Co), zinc (Zn), molybdenum (Mo), titanium (Ti), tungsten (W), tantalum (Ta), manganese (Mn), iridium (Ir), and copper (Cu), an oxide of the one metal, and a sulfide of the one metal.

9. The processing method of claim 8, wherein the gradient film includes molybdenum oxide (MoOx), molybdenum oxysulfide (MoOxS), and molybdenum disulfide (MoS₂).

10. The processing method of claim 1, wherein the gradient film is deposited directly on the substrate.

11. The processing method of claim 1, wherein the gradient film is deposited by an atomic layer deposition (ALD) process.

12. The processing method of claim 1, wherein the gradient film is deposited by a chemical vapor deposition (CVD) process.

13. The processing method of claim 1, wherein the substrate comprises one or more of silicon (Si), silicon oxide (SiO₂), glass, quartz, silicon nitride (Si₃N₄), or silicon oxycarbonitride (SiOCN).

14. The processing method of claim 13, wherein the substrate comprises one or more of a through-glass via (TGV) or a through-silicon via (TSV).

15. The processing method of claim 14, wherein each of the through-glass via (TGV) or the through-silicon via (TSV) independently has an aspect ratio in a range of from 5:1 to 150:1.

16. The processing method of claim 1, further comprising depositing a seed layer directly on the gradient film.

17. The processing method of claim 16, wherein the seed layer comprises one or more of copper (Cu), ruthenium (Ru), cobalt (Co), tungsten (W), or molybdenum (Mo) and has a thickness in a range of from 1 Å to 500 nm.

18. The processing method of claim 1, further comprising depositing a buffer layer directly on the substrate.

19. The processing method of claim 18, wherein the buffer layer comprises one or more of silicon oxide (SiO₂), silicon nitride (Si₃N₄), or silicon oxycarbonitride (SiOCN).

20. The processing method of claim 1, wherein the metallic film is deposited directly on the gradient film.
